(19) United States
(12) Patent Application Publication
(10) Pub. No.: US 2015/0079281 A1
(43) Pub. Date: Mar. 19, 2015

(54) Silica Nano/Micro-Sphere Nanolithography Method by Solvent-Controlled Spin-Coating

(71) Applicants: Jeayoung Choi, Chandler, AZ (US); Christiana Honsberg, Tempe, AZ (US)

(72) Inventors: Jeayoung Choi, Chandler, AZ (US); Christiana Honsberg, Tempe, AZ (US)

(21) Appl. No.: 14/448,118

(22) Filed: Jul. 31, 2014

Related U.S. Application Data
(60) Provisional application No. 61/860,507, filed on Jul. 31, 2013.

(51) Int. Cl. G03F 7/26

(52) U.S. Cl. CPC G03F 7/26
USPC 427/240

(57) ABSTRACT

A method is provided for preparing an etching mask on a substrate. The method includes dispersing a plurality of particles in an aprotic suspending medium to form a suspension and spin-coating the suspension on a substrate to form an etching mask on the substrate.

### CROSS-REFERENCE TO RELATED APPLICATIONS

This application claims the benefit of the U.S. Provisional Patent Application No. 61/860,507 filed on Jul. 31, 2013 and entitled “SILICA NANO/MICRO-SPHERE NANOLITHOGRPAHY METHOD BY SOLVENT-CONTROLLED SPIN-COATING”, the entire disclosure of which is hereby incorporated herein by reference.

### STATEMENT REGARDING FEDERALLY SPONSORED RESEARCH

This invention was made with government support under 1041895 awarded from the National Science Foundation and the Department of Energy. The United States government has certain rights in the invention.

### BACKGROUND OF THE INVENTION

The field of the invention relates to colloidal particles, and more specifically, to disposing colloidal particles for preparing an etching mask on a substrate.

Use of two-dimensional (“2D”) self-assembled colloidal particles has permeated many technological areas including fabrication at the micrometer and nanometer scale of electronic and optical devices, biochips, biosensors, and so forth, using lithographical methods. Applications span a variety of industries, including renewable energy, telecommunications, information processing, illumination, spectroscopy, holography, medicine, military technology, agriculture and robotics.

Due to the wide range of applications, many techniques have been developed to produce uniform colloidal particle 2D assemblies with large area coverage, including Langmuir-Blodgett deposition, convective self-assembly, and dip-coating. Although conventional techniques have been successful in achieving closely packed 2D colloidal particle assemblies with high uniformity, the slow processes and restricted coverage area have been considered as barriers for their further applications.

Recently, methods have been developed to offer faster and less expensive alternatives to producing large-area colloidal particle 2D assemblies. This includes suspending colloidal particles in specific solvents, such as methanol or water, and dispersing them on wafer substrates using spin-coating techniques. However, the limited properties of conventional solvents, have been made such processes challenging due to poor surface wettability and fast evaporation rates during spin-coating. To address these issues, some approaches have included adding surfactants to the solvent solutions to improve wettability and reduce the evaporation rates. Others have excluded surfactants, and instead introduced systems for controlling humidity and temperature during spin-coating in order to slow down solvent evaporation rates. Such approaches include additional processing steps and system overhead.

Therefore, given these shortcomings, it would be desirable to have a low-cost, high-throughput method for arranging colloidal particle assemblies onto desired substrates.

### SUMMARY OF THE INVENTION

The present invention overcomes the aforementioned drawbacks by providing an approach for assembling particles with high coverage and close packing. In particular, a suspending medium and processing method is introduced for suspending and dispersing desired particles, such as colloidal particles, onto a substrate, for example, in a spin-coating process, without need for surfactant-based mixtures or environmental control systems.

Among other uses, the present invention can be applied to manufacturing processes of electronic and optical devices, biochips, biosensors, and the like. For instance, colloidal particles, assembled onto a substrate in a manner described by the present disclosure, can be used for surface treatment processes during fabrication of photovoltaic cells. By way of example, such surface treatment can include an etching step, such as a plasma etch, reactive ion etch, or another physical or chemical etch, or material removal step. As such, the dispersed particles can serve as etch masks for shaping, texturing, or profiling a substrate surface in dependence of particle size, composition, and surface arrangement. Alternatively, it may be appreciated that other processes in combination with techniques described herein, are also possible. For example, colloidal particles dispersed onto a substrate in accordance with the present disclosure can be used as masks during material deposition steps.

In one embodiment of the present invention, a method for preparing an etching mask on a substrate is provided. The method includes dispersing a plurality of particles in an aprotic suspending medium to form a suspension. The method also includes spin-coating the suspension on a substrate to form an etching mask on the substrate.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a graphical illustration comparing dispersibility of silica micro-spheres (“SMS”) suspended in N,N-dimethyl-formamide (“DMF”) and water. (a) calculated and measured absorbance; scanning electron microscopy (“SEM”) images of SMS assemblies using (b), DMF and (c) water.

FIG. 2 shows a SEM image illustrative of the SMS cluster effect producing non-uniform SMS distribution during spin-coating.

FIG. 3 shows: a contact angle measurement of (a) water and (b) DMF; a comparison of surface coverage with 300 ul (100 mg/ml) for (c) SMS_{water} and (b) SMS_{DMF} solution droplets on 2-inch Si substrate; and surface images of (e) SMS_{water}, and (f) SMS_{DMF}.

FIG. 4 shows SEM images comparing the coverage difference between (a) SMS_{DMF} and (b) SMS_{water}.

FIG. 5 is a schematic illustration of two spheres partially immersed in a fluid layer for capillary attraction, F_{cap}.

FIG. 6 is a schematic illustration of (a) fast solvent evaporation, and (b) slow solvent evaporation during spin-coating, producing (c) localized SMS assembly with discontinuous F_{cap}, and (d) long-range SMS assembly after expanded F_{cap}.

FIG. 7 shows SEM images for SMS coverage from various concentration of SMS_{DMF}, which are (a) 50 mg/ml, (b)100 mg/ml, and (c) 150 mg/ml.

FIG. 8 shows SEM images illustrative of the acceleration rate effect for uniform SMS assembly layer formation; (a) 20 rpm/s, (b) 50 rpm/s, and (c) 80 rpm/s.

FIG. 9 shows a surface image of (a) SMS deposited on a 2-inch round Si substrate, and the corresponding SEM images at different magnifications of (b) 250×, (c) 2000×, and (d) 25000×, respectively.

FIG. 10 shows a surface image of (a) SMS deposited on a 4-inch round Si substrate, and the corresponding SEM image at magnification (b) 100×; SEM images (c) and (d) represent regions of low and high SMS monolayer coverage, respectively.

### DETAILED DESCRIPTION OF THE INVENTION

Production of modern-era devices, with increased complexity and ever-decreasing dimensions, has required overcoming many technical challenges associated with approaching fundamental physical limits. As such, the physical scale of colloidal particles have found important uses in device fabrication, and particularly in photovoltaic cell manufacturing, where the need for increased cell efficiency and reduced cost has pushed the technology toward reduced dimensionality and enhanced energy absorption.

Specifically, the size, self-assembly and etch properties of colloidal particles lend themselves well to substrate surface shaping and profiling at the micrometer and nanometer scale. For example, colloidal particles may be utilized to create features or patterns on a substrate, by forming assemblies that can be used as etch or deposition masks during a fabrication process. The shape, texture, or profile of substrate surfaces resulting from application of an etching step, for instance, depending upon colloidal particle arrangement and dimensions, may be utilized to generate substrate feature sizes in a range between, 10 nanometers to 10 micrometers. However, technical challenges remain for obtaining uniform monolayer distribution over extended areas on a substrate, for example, using a spin-coating process.

Recognizing the shortcomings of previous techniques, the present invention provides an approach for achieving superior colloidal particle uniformity over large substrate areas. For example, as will be described, by utilizing a suspending medium with a relatively slow rate of evaporation, as compared to say water, a more consistent convective flux of the particles and medium, the particles dispersed or suspended therein, can be achieved during a spin-coating process. Similarly, by utilizing a suspending medium in which the particles are evenly or uniformly dispersed before a spin-coating process begins, a uniformity of a resultant layer may be further improved. For example, an aprotic medium for suspending colloidal particles may be used, since such medium can possess characteristics that improve the effectiveness of the spin-coating process.

Particles, to include colloidal particles, and for use in accordance with aspects of the present disclosure, may be generally sized to an average dimension in the range of 10 nanometers to 10 micrometers, and shaped to be spherical, ellipsoidal, and the like, although other shapes and sizes may be possible. Particularly, the average dimension typically refers to the longest longitudinal length common to the plurality of particles. The particles may be manufactured using suitable materials and methods, in accordance with a desired application. By way of non-limiting example, the particles may comprise metal oxides, or silica, or alumina, or zirconia, or titania, or carbon, or any combination thereof. The particles may be dispersed in a suspending medium, using suitable techniques, such as sonication, to form a suspension with properties according to a desired concentration, or other criteria. For example, the concentration of the plurality of particles in the suspending medium can be in the range of 0.1 to 10.0 wt %, although other values are possible.

By way of non-limiting example, a suspending medium, for use in accordance with the present disclosure, can be an amide solvent, or a hydrophilic solvent, or a suspending medium selected from a group consisting of tetrahydrofuran, ethyl acetate, acetone, dimethylformamide, acetonitrile, dimethyl sulfoxide, and mixtures thereof. In some aspects of the invention, the suspending medium does not include a surfactant. In other aspects of the invention, the suspending medium may be dimethyl-formamide. In addition, the suspending medium can have a boiling temperature in the range of 100 degrees Celsius to 200 degrees Celsius, or a viscosity in the range of to 0.1 mPa sec to 1.0 mPa sec at 25 degrees Celsius, or a surface tension in the range of 20 mN/m to 40 mN/m at 25 degrees Celsius, or combinations thereof, although other values are possible. As will become apparent, suspending media, with properties as described, facilitate dispersiblity, wettability, and evaporation requirements for obtaining an enhanced uniformity of particles on a substrate.

The suspension, or solution containing the particles dispersed in the suspending medium, can then be distributed onto a substrate in any manner using, for example, a spin-coating process. In some aspects, the suspension can undergo a rotational acceleration to a rotational target speed between 1000 and 5000 rotations per minute, wherein the rotational acceleration can be in the range of 50 rotations per minute per second to 100 rotations per minute per second, although other rotational acceleration and speed values, along with multiple rotational stages and durations, may be possible. In addition, the substrate may be of any type, and can include materials such as silicon, although it may be appreciated that other substrate types and substrate materials may also be possible. In certain aspects, the dispersed particles form a two-dimensional (“2D”) self-assembled layer on a substrate surface. In other aspects, a monolayer coverage of the particles on the substrate can be in the range of 80% to 100% of the surface of the substrate, although other values may be possible.

A specific example is provided below. This example is offered for illustrative purposes only, and is not intended to limit the scope of the present invention in any way. Indeed, various modifications of the invention in addition to those shown and described herein will become apparent to those skilled in the art from the foregoing description and the following example and fall within the scope of the appended claims. For example, a specific example of an aprotic suspending medium and colloidal particles are provided below, although it will be appreciated that other suspending mediums and particles may also be used. Likewise, process parameters are recited (for example, rotational speed or acceleration during a spin-coating process) that may be altered or varied based on variables such as particle size, suspending medium viscosity, and so forth.

### EXAMPLE 1

Polished n-type Si (100) round substrates, 2-inch and 4-inch in diameter with 280 μm and 460 μm thickness, respectively, were used to demonstrate the dispersibility of particles on a substrate. As a preparation step, the substrates were cleaned in piranha solution [H₂SO₄ (96%): H₂O₂ (30%)=4:1] for 15-min to form hydrophilic Si surface followed by 10-min de-ionized water (DI-water) rinse.

Next, silica micro-sphere (SMS) solutions for spin-coating were prepared by adding 310 nm-diameter silica microsphere powder to separate solvents, namely N,N-dimethyl-formamide (DMF) and de-ionized water. The solutions were subjected to a sonication process for 5 hours to agitate the particles in order to produce complete dispersion of SMS in the solution. The SMS dispersion for each solvent was then characterized by measuring absorbance using ultraviolet-visible (UV-VIS) spectrophotometer. Subsequently, the solutions were spin-coated onto the Si substrates, using a Delta80BN spinner (SUSS MicroTec), under ambient laboratory conditions (21-23° C. temperature and 25-30% humidity). A single step of spin-coating recipe was implemented using various acceleration rates (20-80 rpm/s) for 2000 rpm target speed. The SMS spin-coated substrates were subsequently examined by scanning electron microscopy (SEM, JEOL XL-30), and coverage of SMS was calculated using image analysis software, “Image J” (National Institutes of Health, USA) after the direct counting of the SMS area. The wettability of solvent on Si wafer was assessed by measuring contact angle with EasyDrop contact angle measurement system (KRUSS).

To prove the effectiveness of using DMF for 2D colloidal particle spin-coating on large-scale surface area, one of the most widely used solvent, namely water, has been selected to compare the quality of SMS monolayer assembly layer, and the coverage after spin-coating under ambient conditions.

### Dispersibility in Solution

Before performing a spin-coating of particles dispensed in a suspending medium for use in, for example, a lithographical process, a uniform dispersion of particles in the medium may be advantageous to avoid clustered deposition on a substrate surface. Therefore the choice of medium, such as N,N-dimethyl-formamide (“DMF”), helps to ensure a high dispersibility.

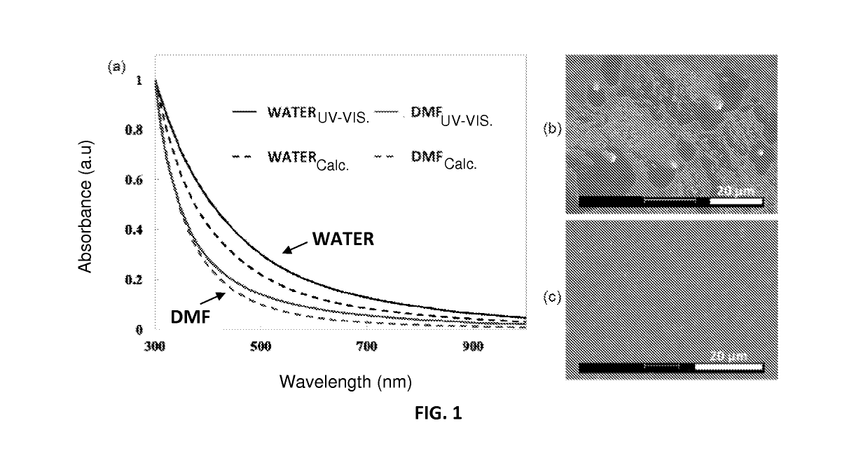

Turning to FIG. 1(a) a plot of absorbance versus wavelength is shown for 0.5 wt % 310 nm SMS dispersed in DMF (denoted as SMS_{DMF}) and water (denoted as SMS_{water}). Using a UV-VIS spectrophotometer, normalized absorbance measurements (solid lines) were performed to compare SMS dispersibility for each solvent. Also, extinction cross-sections calculations for a single SMS of the same size (dashed lines) were fitted to the experimental measurements (solid lines). As shown, DMF produces a high level of SMS dispersibility since the measured absorbance (denoted as DMF_{UV-VIS}) of SMS in DMF has a very well-matched trend with the calculated extinction cross-section (denoted as DMF_{calc}), indicating SMS_{DMF} was nearly completely dispersed. By contrast, for SMS_{water} the experimental absorbance (denoted as WATER_{UV-VIS}) was substantially broadened compared to calculated extinction cross-section (denoted as WATER_{calc}). This spectral broadening of absorbance suggests that particles larger than 310 nm are dispersed in the water solution, which appears to result from aggregated SMS. FIG. 1(b) and FIG. 1(c) highlight the dispersivity difference between spin-coated solutions of SMS_{DMF} and SMS_{water}, wherein FIG. 1(b) shows the appearance of clusters on the substrate surface.

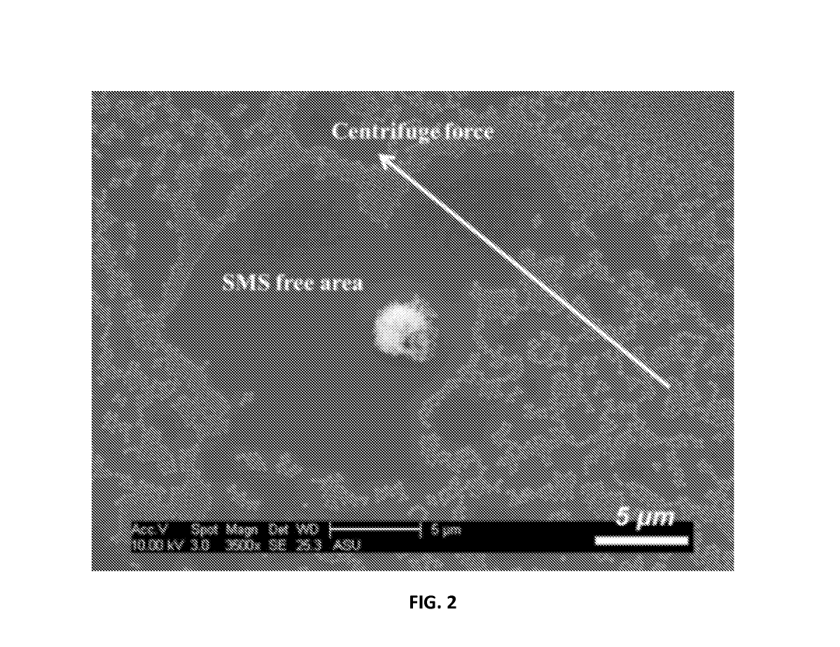

The existence of a large number of SMS clusters in a dispensed solution helps to produce uniform monolayer deposition during spin-coating. Due to a heavier weight, and hence higher surface friction, clusters can anchor to the substrate surface and consequently act as a flow barrier, preventing uniform distribution of the SMS. This is illustrated in FIG. 2, in which poor SMS dispersibility in a solvent is shown to produce a large, SMS-free area a radial direction induced by the spinning process, and thus significantly affecting the coverage of SMS monolayer. Therefore, a high level of SMS dispersibility in solution is desired to produce a high uniformity and coverage of SMS monolayer following spin-coating.

### Wettability on Silicon Substrates

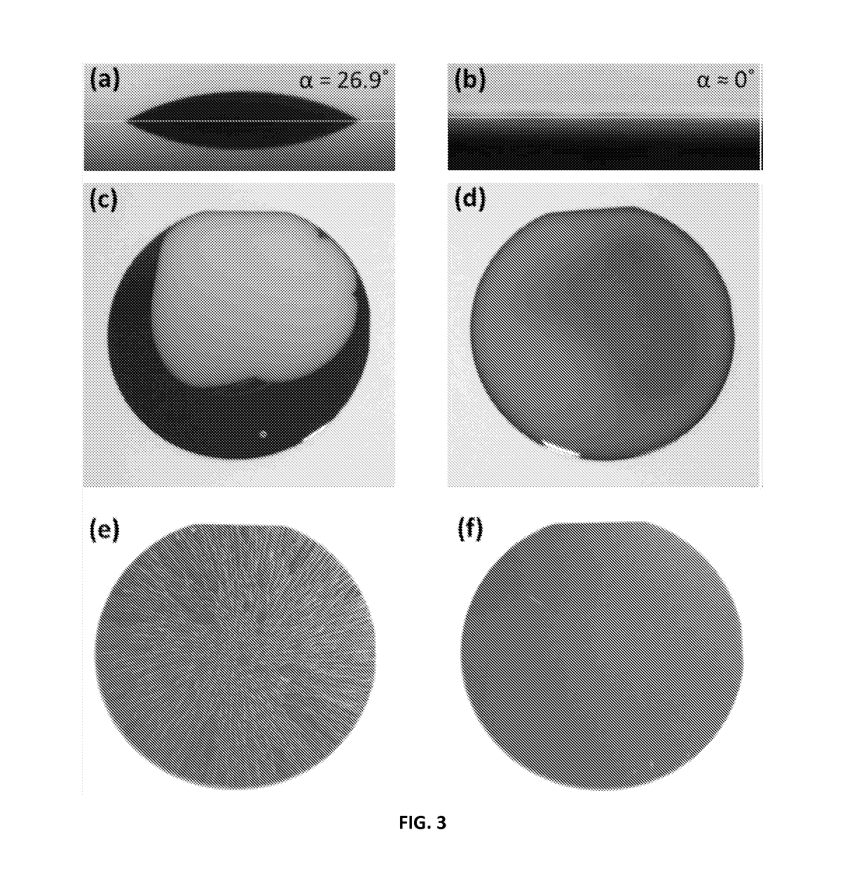

Turning to FIG. 3, the contact angles (α) of DMF and water on Si surface were measured to compare the degree of wettability of each solvent. Comparing FIGS. 3(a) and 3(b), DMF is shown to offer an outstanding wettability [α_{DMF}≈0 in FIG. 3(b)] compared to water [α_{water}=26.9° in FIG. 3(a)] on the piranha cleaned Si surface. The importance of solvent wettability is a crucial factor to obtain highly uniform monolayer coverage, the reason being that a high wettability can provide fast, uniform, and omni-directional spread-out during (or even before) the spin-coating step due to a low surface tension. For a wettability comparison between DMF and water, 300 ul volume solutions of 100 mg/ml SMS_{water} and SMS_{DMF} were been dispensed on piranha-cleaned 2-inch Si substrates. From FIGS. 3(c) and 3(d), it is clear that the SMS_{DMF} solution shows a complete wetting layer on the surface once the solution was dropped, whereas the same solution volume of SMS_{water} produced only a partially-covered surface.

The significance of wettability for spin-coating is illustrated in FIGS. 3(e) and 3(f), where the surface uniformity of SMS_{water} and SMS_{DMF} after spin-coating is illustrated. The images clearly illustrate that, unlike water-based solution, a DMF-based solution can produce outstanding uniformity from the center of the substrate all the way to the edge. The significantly improved uniformity can be explained by the low surface tension (γ) of DMF (γ_{DMF}=25 mN/m) as compared that of water (γ_{water}=73 mN/m). For high γ solvent (e.g. water), a strong centrifugal force improves solution distribution. However, a strong centrifugal force is achieved by a high rotation speed, which in turn will also cause fast solvent evaporation. A fast evaporation can then remove a significant solvent volume before a uniform SMS distribution can made. As such, formation of non-uniform SMS layer is unavoidable, and thus a low γ solvent is more desirable for uniform SMS assembly.

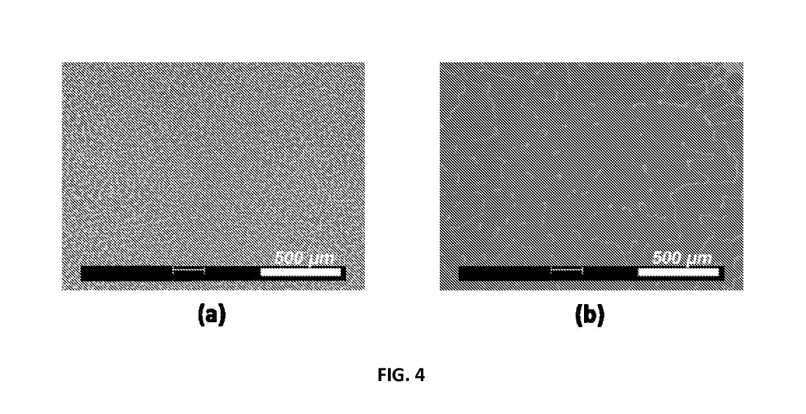

In addition, a low γ is also beneficial to producing a large SMS coverage. This is because a lower y solvent, utilizing slower spinning speeds, produces only small amounts of SMS loss in the spinning process. By contrast, a high γ solvent produces a large loss of SMS due to the strong centrifugal force to distribute the solution during spin-coating. This difference is illustrated in FIG. 4, wherein SEM images reveal a very noticeable coverage improvement of SMS_{DMF} over SMS_{water}. For this example, the images were obtained at the center of each substrate to exclude possible secondary SMS delivery during solution spreading. Therefore, it is clear that the great wettability of DMF can offer excellent uniformity in the assembled SMS layer, with outstanding coverage and small loss of SMS.

### Solvent Evaporation Rate

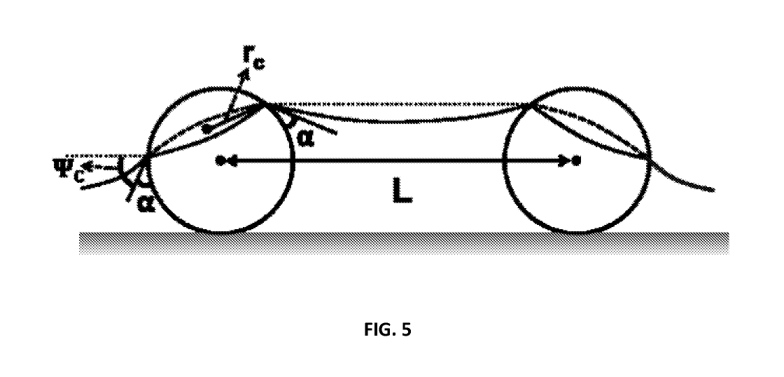

For highly uniform and closely-packed SMS monolayer formation using a spin-coating approach, two processes should be efficiently taken into account, namely the (1) capillary assembly, and (2) convective flux. Turning to FIG. 5, capillary assembly, which uses capillary forces to organize particles in a suspension, is dominant at the short range because the magnitude of capillary force is inversely proportional to the inter-particle distance, as follows:

F_{cap}=2πγr_{c}²(sin²Ψ_{c})(1/L) (1)

where γ is the surface tension of a liquid, r_{c} is the radius of the three-phase contact line at the particle surface, Ψc is the mean meniscus slope angle at the contact line, and L is the distance between the centers of the particles as is illustrated in FIG. 5

To generate a close-packed SMS monolayer over an expanded surface area, a sufficient particle flux provides for uninterrupted growth of SMS assembly monolayer. Therefore, an effective SMS flux should follow initial nucleation of SMS monolayer caused by an initial capillary assembly. For a spin-coating process, this SMS flux may be convective, which originates from the different hydrodynamic forces induced by the variation in wetting layer thickness from substrate center to edge while spinning.

The evaporation of solvent induces a gradual decrease of the wetting layer thickness with time, and until the wetting layer is thicker than the SMS diameter, it decreases evenly over wetting area. Once ordered regions are formed, there would be solvent convective flux from thicker wetting (or disordered) region to thinner wetting (or ordered) region followed by SMS flux. During this convective flux, there is a different evaporation rate between ordered and disordered regions due to the slower solvent evaporation rate in the ordered region caused by hydrophilic property of the SMS. With water, however, its high vapor pressure (VP_{water}=17.54 Torr at 20° C.) leads a rapid evaporation rate at disordered region during spin-coating, and produces fast reduction of fluid level variation from ordered region to disordered region.

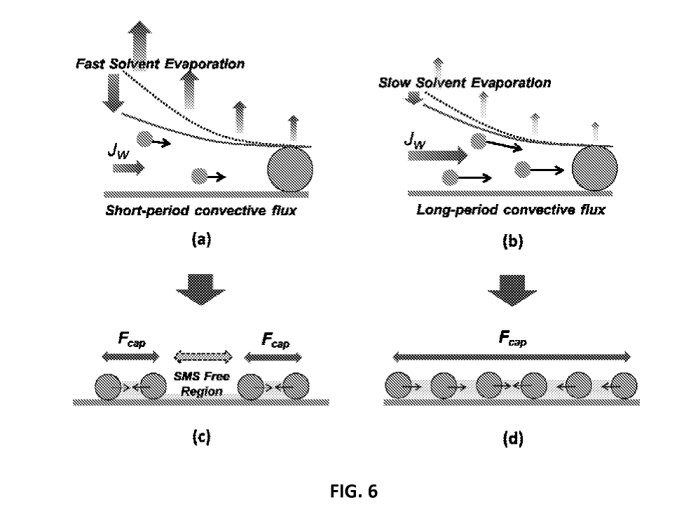

This process is illustrated in FIG. 6. For a solution with a fast evaporation rate, convective flux may only occur for short period of time. As such, an insufficient convective flux as illustrated in FIG. 6(a) leads to only a short-range SMS ordered region, formed through a localized F_{cap}, as shown in FIG. 6(c). Consequently, in order to achieve long-range SMS assembly, solvents with high vapor pressure (e.g. water, methanol) have required additional treatment involving surfactants or have necessitated systems for temperature and humidity control in order to provide delayed evaporation.

By contrast, DMF, has a slow evaporation rate caused by its low vapor pressure (VP_{DMF}=2.7 Torr at 20° C.), which can then lead to the long period convective flux needed to deliver sufficient amount of SMS from disordered region to ordered region, shown in FIG. 6(b). Consequently, a long range SMS assembled region can be achieved, with an expanded F_{cap} on the substrate surface, shown in FIG. 6(d). The slow evaporation rate of DMF, combined with excellent dispersibility and enhanced wetting properties have successfully produced well close-packed SMS monolayer assembly with an outstanding coverage on the surface, as will be shown in following section.

Large-Scale Area SMS Monolayer Spin-Coating with DMF

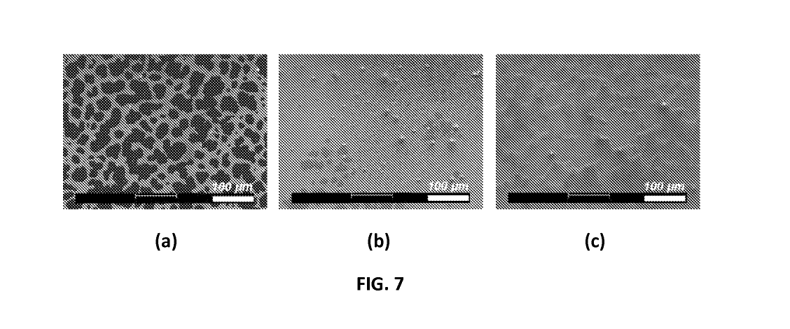

In addition to the choice of solvent, the solution concentration and spin-coating speeds are also effective parameters in assembling highly uniform SMS monolayers with great coverage on large-scale surface area. Turning to FIG. 7, the effect of SMS_{DMF} concentration on substrate coverage is illustrated. The figure shows SEM images of spin-coated substrates using 50 mg/ml, 100 mg/ml, and 150 mg/ml of SMS_{DMF}, without a spin-coating process optimization, namely 20 rpm/s acceleration, 2000 rpm for 150 sec. It can be seen that a higher SMS coverage is achieved with increased concentration, and at 150 mg/ml SMS_{DMF}, a complete surface coverage was formed after spin-coating. However, with increased concentrations of SMS_{DMF} a more severe non-uniformity of SMS assembly layer is observed, which may be due to the increased viscosity of solution at higher SMS concentrations. Therefore, a well-optimized spin-coating process is necessary for uniform distribution of SMS over the substrate surface.

Previously, for self-assembled microsphere (MS) monolayer deposition, conventional spin-coating processes involve two steps: (1) a dispersion step at slow speed rotation for uniform MS distribution on the surface, and (2) a drying step at high speed rotation for removing solvent residue and prevent further solvent interaction with MS after spin-coating. This two-step spin-coating process has been developed because the conventional solvents, like water, have a high y that produce a large loss of MS for high spinning speeds. Moreover, fast evaporation rates at high speeds prevented the manufacture of uniform MS assembly. As such, a slow spin speed dispersion step is needed for increased uniformity with reduced MS loss.

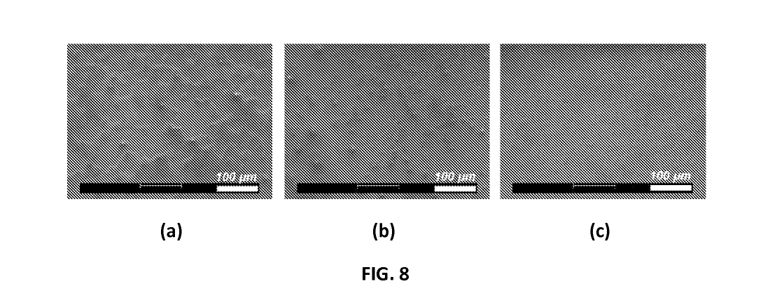

However, with DMF only a one step spin-coating process may be sufficient due to the great wettability and slow evaporation rate. In the example process, target speed is fixed at 2000 rpm, and only acceleration rates are changed, for a total of 150 sec spin-coating duration. Turning to FIG. 8, the effect of acceleration on the formation of a SMS assembly layer is shown. The figure shows SEM figures of coverage obtained using accelerations of 20 rpm/s, 50 rpm/s, and 80 rpm/s. As the acceleration rate is increased, an enhanced surface morphology of SMS assembly layers is observed, whereby at 80 rpm/s acceleration a uniform SMS monolayer is achieved.

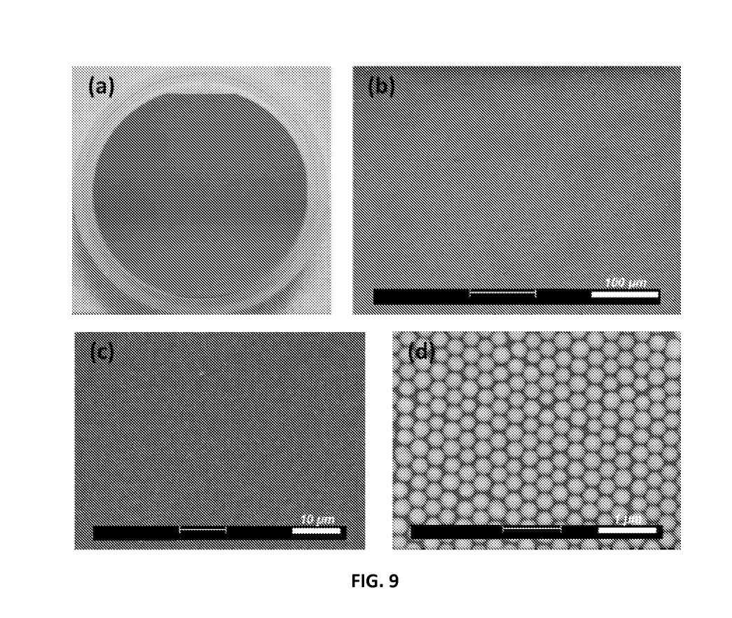

Turning to FIG. 9(a), the image of 2-inch substrate is shown after undergoing spin-coating with 80 rpm/s acceleration. Aside from insignificant surface defects, examining the SMS monolayer at high magnification in FIG. 9(d), the overall uniformity is excellent. Moreover, more than 95% of average coverage has been achieved, which is the highest SMS monolayer coverage on 2-inch substrates ever reported by spin-coating.

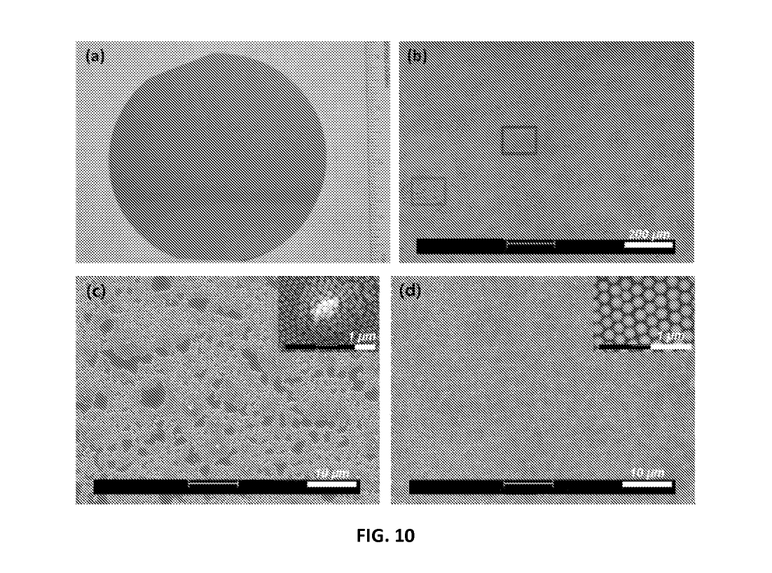

Turning now to FIG. 10, in order to explore the feasibility of DMF for SMS monolayer assembly on even larger-scale, 4-inch round Silicon (Si) substrates were prepared. An identical spin-coating recipe and SMS_{DMF} concentration was applied to examine the area dependence, and only the solution volume was adjusted to 800 μl to account for the increased surface area. The figure demonstrates a great overall coverage of SMS monolayer on the 4-inch substrate, with great uniformity from center to edge. Although FIG. 10(c) identifies a few areas with relatively low SMS coverage, consideration should be made that the process has not been optimized for 4-in area deposition. As such these issues may be resolved by further adjustment of spin-coating process or solution concentration. Nevertheless, this process provides more than 90% of average monolayer coverage, which is still a superb SMS coverage assembled by a spin-coating process. In addition, it should be highlighted that these results were achieved by spin-coating under common ambient laboratory conditions, without any surfactant mixture or additional treatment on the substrate and SMS. Therefore, the unique solvent properties of DMF are believed to offer a high tolerance to large-scale surface area SMS spin-coating accompanied by outstanding SMS monolayer uniformity and coverage.

In the present invention, a new organic solvent, N,N-dimethyl-formamide (DMF) is introduced for silica microsphere (SMS) monolayer spin-coating on Si surface, which has proven its great potential for high-throughput spin-coating process application leading large-scale area coverage of well close-packed SMS monolayer assembly without any surfactant mixture and environment control during spin-coating. We showed that the DMF can provide outstanding competence to replace conventional solvents, (e.g. water, and methanol) to enhance the uniformity, coverage, and packing of SMS monolayer even under the ambient laboratory spin-coating environment.

From a comparison with water, DMR was shown to offer enhanced properties for spin-coating applications. As demonstrated, DMF allows for well-dispersed SMS in the medium that is close the theoretical limit, which is an important property in producing a uniform SMS distribution on the surface of a substrate. Moreover, the outstanding wettability of DMF forming a thin wetting layer on the substrate surface provides superb coverage of SMS assembly layer compared to same volume and concentration of SMS in water. As such, a more than 90% of SMS monolayer assembly has been demonstrated on 2-inch (˜95%) and 4-inch (˜90%) Si substrates without need for additional surfactant additives, or special environment control, such as humidity and temperature, for the spin-coating process. Advantageously, DMF offers a great potential for a high-throughput, simple, and low-cost spin-coating process to produce a highly uniform 2D colloidal particle assembly on large-scale deposition area.

The present invention has been described in terms of one or more preferred embodiments, and it should be appreciated that many equivalents, alternatives, variations, and modifications, aside from those expressly stated, are possible and within the scope of the invention.

What is claimed is:

1. A method for preparing an etching mask on a substrate, the method comprising:
a. dispersing a plurality of particles in an aprotic suspending medium to form a suspension; and
b. spin-coating the suspension on a substrate to form an etching mask on the substrate.

2. The method of claim 1, wherein the plurality of particles are colloidal particles.

3. The method of claim 1, wherein the plurality of particles are generally shaped to be ellipsoidal, spherical, or any combination thereof.

4. The method of claim 1, wherein the plurality of particles are generally sized to an average dimension in the range of 10 nanometers to 10 micrometers.

5. The method of claim 1 wherein the plurality of particles are metal-oxides.

6. The method of claim 1, wherein the plurality of particles comprise silica, alumina, ceria, zirconia, titania, carbon, or any combination thereof.

7. The method of claim 1, wherein the suspending medium is an amide solvent.

8. The method of claim 1, wherein the suspending medium is selected from a group consisting of tetrahydrofuran, ethyl acetate, acetone, dimethylformamide, acetonitrile, dimethyl sulfoxide, and mixtures thereof.

9. The method of claim 1, wherein the suspending medium is hydrophilic.

10. The method of claim 1, wherein the suspending medium has a boiling temperature in the range of 100 degrees Celsius to 200 degrees Celsius.

11. The method of claim 1, wherein the suspending medium has a viscosity in the range of to 0.1 mPa·sec to 1.0 mPa·sec at 25 degrees Celsius.

12. The method of claim 1, wherein the suspending medium has a surface tension in the range of 20 mN/m to 40 mN/m at 25 degrees Celsius.

13. The method of claim 1, wherein the suspending medium is dimethylformamide.

14. The method of claim 1, wherein a concentration of the plurality of particles in the suspending medium is in the range of 0.1 to 10.0 wt %.

15. The method of claim 14, wherein the concentration of the plurality of particles in the suspending medium is in the range of 0.1 to 1.0 wt %.

16. The method of claim 1, wherein the suspension undergoes a rotational acceleration to a rotational target speed between 1000 and 5000 rotations per minute.

17. The method of claim 16, wherein the rotational acceleration is in the range of 50 rotations per minute per second to 100 rotations per minute per second.

18. The method of claim 1, wherein a monolayer coverage of the plurality of particles on the substrate is in the range of 80% to 100%.

19. The method of claim 1, wherein the substrate comprises silicon.

20. The method of claim 1, wherein the suspending medium does not include a surfactant.
